(19) United States
(12) Patent Application Publication
(10) Pub. No.: US 2023/0225096 A1
(43) Pub. Date: Jul. 13, 2023

(54) ELECTROMAGNETIC WAVE ABSORBING MATERIAL, PREPARING METHOD THEREOF AND COMPOSITE STRUCTURE FOR SUPPRESSING ELECTROMAGNETIC INTERFERENCE

(71) Applicant: Industrial Technology Research Institute, Chutung (TW)

(72) Inventors: Chun-Pin WU, Chutung (TW); Mean-Jue TUNG, Chutung (TW); Shi-Yuan TONG, Chutung (TW); Wen-Song KO, Chutung (TW); Yu-Ting HUANG, Chutung (TW)

(21) Appl. No.: 18/148,003

(22) Filed: Dec. 29, 2022

(30) Foreign Application Priority Data
Dec. 30, 2021 (TW) 110149762

(51) Int. Cl. H05K 9/00

(52) U.S. Cl. CPC H05K 9/0083; H05K 9/0088

(57) ABSTRACT

The present disclosure provides an electromagnetic wave absorbing material, including a core containing iron oxide having a first thermal expansion coefficient; and a shell layer covering the core, which has a second thermal expansion coefficient less than the first thermal expansion coefficient, and the shell layer contains an inorganic compound selected from a group consisting of oxides, nitrides or any combination thereof. The present disclosure further provides a composite structure for suppressing electromagnetic interference including the electromagnetic wave absorbing material as claimed.

### CROSS-REFERENCE TO RELATED APPLICATIONS

This application claims priority to Taiwan Patent Application No. 110149762, filed on Dec. 30, 2021, and Taiwan Patent Application No. 111150731, filed on Dec. 29, 2022. The entirety of the above-mentioned patent application is hereby incorporated by reference herein and made a part of this specification.

### TECHNICAL FIELD

The present disclosure relates to a material and a composite structure for suppressing electromagnetic interference, and more particularly, to a material and a composite structure for absorbing electromagnetic waves.

### BACKGROUND

With the continuous development of communication technology, high-density, thin, and multi-antenna integration packaging become a trend. However, the change of the trend has gradually reduced the spacing between components, producing a strong electromagnetic coupling effect. At the same time, it is also accompanied by electromagnetic interference (EMI) undergoing multiple reflections and resonances out of modules, between components, and inside a substrate. These not only increase the cost of the background noise process, but also reduce the performances of components and modules, weaken the strength of the signal, even affect the delay and reliability of signal transmission, and hardly maintain a good communication quality.

A technical means to coat a metal layer outside a module is reported in the art. The metal layer is used to isolate electromagnetic waves to achieve the effect of suppressing electromagnetic interference. However, the metal layer with the above technical means only provides an effect of reflecting electromagnetic waves. Although the impact of electromagnetic waves outside the module is eliminated, radiated electromagnetic interference within the module and high-order noise harmonics generated by the resonance effect still cannot be suppressed. As a result, the electromagnetic interference issue still exists.

In view of this, it is necessary to propose a material and a structure that effectively suppress electromagnetic interference to improve the impact of electromagnetic interference and improve the communication quality of application products.

### SUMMARY

The present disclosure provides an electromagnetic wave absorbing material, the electromagnetic wave absorbing material includes: a core, containing an iron oxide and having a first thermal expansion coefficient; and a shell layer, covering the core, wherein the shell layer has a second thermal expansion coefficient less than the first thermal expansion coefficient, and the shell layer contains an inorganic compound selected from oxides, nitrides or any combination thereof.

The present disclosure also provides a method for manufacturing an electromagnetic wave absorbing material, the method includes the following steps: providing a shell layer material precursor and a core material precursor; coating the core material precursor with the shell layer material precursor to form a combination; sintering the combination at a high temperature to form a core and a shell layer, wherein materials of the core and the shell layer diffuse with each other; and etching the shell layer.

In addition, the present disclosure further provides a composite structure for suppressing electromagnetic interference, comprising the aforementioned electromagnetic wave absorbing material, functional filler, and matrix.

### BRIEF DESCRIPTION OF THE DRAWINGS

Embodiments of the present disclosure are illustrated with reference to drawings:

FIG. 1 is a schematic structural view of an electromagnetic wave absorbing material of the present disclosure;

FIG. 2 is a schematic structural view of a composite structure of the present disclosure;

FIGS. 3A to 3E are X-ray diffraction patterns of examples 1, 2, 7, 8, 14 of the present disclosure;

FIGS. 3F to 31 are X-ray diffraction patterns of comparative examples 1 to 4 of the present disclosure;

FIGS. 4A to 40 are time domain spectrograms of examples 1 to 15 of the present disclosure;

FIGS. 5A to 5D are X-ray diffraction patterns of examples 16, 18, 19, 20 of the present disclosure;

FIGS. 6A to 6D are energy dispersive X-ray spectra (EDS) of examples 1, 16-1, 16-2, 16-3 of the present disclosure;

FIGS. 7A to 7C are time domain spectrograms of examples 21 to 24 and comparative examples 5 of the present disclosure; and

FIG. 8 shows temperature-dimension variation curves of examples 25-27 of the present disclosure.

### DETAILED DESCRIPTIONS

The following describes the implementation of the present disclosure with examples. Those familiar with the art can easily understand the other advantages and effects of the present disclosure from the content disclosed in this specification. The present disclosure can also be implemented or applied in other different implementations, details in this specification can also be modified and varied based on different views and applications without departing from the spirit disclosed in the present disclosure. Furthermore, all ranges and values herein are inclusive and combinable. Any value or point falling within the range stated in this specification such as any integer can be used as a minimum or maximum value to derive a hyponym range etc.

According to the present disclosure, an electromagnetic wave absorbing material is provided and includes: a core, containing an iron oxide and having a first thermal expansion coefficient; and a shell layer, covering the core, wherein the shell layer has a second thermal expansion coefficient less than the first thermal expansion coefficient, and the shell layer contains an inorganic compound selected from oxides, nitrides or any combination thereof.

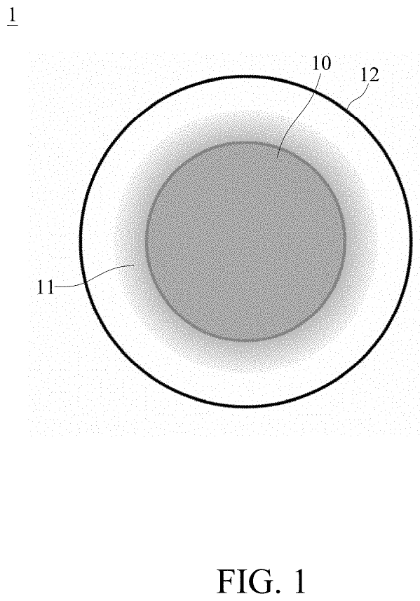

In an embodiment, the electromagnetic wave absorbing material of the present disclosure further includes an amorphous intermediate layer. See FIG. 1, the electromagnetic wave absorbing material 1 has a three-layer core-shell structure, including: a core 10 containing iron oxide, an amorphous intermediate layer 11 disposed between the core 10 and a shell layer 12, and the shell layer 12 containing an inorganic compound. Besides, the amorphous intermediate layer 11 comprises an iron oxide diffused from the core 10 and an inorganic compound diffused from the shell layer 12.

Herein, “iron oxide” used in the core has a magnetic moment capable of interacting with the electromagnetic waves to absorb the noise of electromagnetic interference effectively. In an embodiment, the iron oxide is ferric oxide; and in another embodiment, a crystal form of the iron oxide is orthorhombic, and has an excellent absorption effect with respect to electromagnetic waves higher than 160 GHz, therefore it can suppress the impact of radiated electromagnetic waves within the module, or high-order noise harmonics generated by resonance effect.

In an embodiment, the iron oxide can further be doped with element M, the iron oxide is represented as follows,

MₓFe₂₋ₓO₃

wherein an oxidation number of M is +1, +2, +3, +4, +5, or +6; and x is a value between greater than or equal to 0 and less than 1, such as 0.1, 0.15, 0.2, 0.25, 0.3, 0.35, 0.4, 0.45, 0.5, 0.55, 0.6, 0.65, 0.7, 0.75, 0.8, 0.85, 0.9, or 0.95.

In another embodiment, the element M can be at least one metal element independently selected from a group consisting of molybdenum (Mo), zirconium (Zr), magnesium (Mg), cerium (Ce), lanthanum (La), yttrium (Y), titanium (Ti), silver (Ag), aluminum (Al), gallium (Ga), barium (Ba), rhodium (Rh) and nickel (Ni). In another embodiment, the element M is absent, or one, two, or more. By means of doping the element M, the element M can be doped into the spacing of an iron oxide lattice structure or replaces the iron element in the original lattice. This changes the magnetic moment interaction in the electromagnetic wave absorbing material, further regulates the frequency band of the electromagnetic wave that it can absorb, and in particular, is suitable for the electromagnetic wave frequency band from 105 to 183 GHz.

In specific, when M is molybdenum and x is 0.2, the absorbing frequency of the electromagnetic wave absorbing material is 180 GHz; when M is zirconium and x is 0.2, the absorbing frequency of the electromagnetic wave absorbing material is 172 GHz; when M is magnesium and x is 0.2, the absorbing frequency of the electromagnetic wave absorbing material is 176 GHz; when M is cerium and x is 0.2, the absorbing frequency of the electromagnetic wave absorbing material is 178 GHz; when M is lanthanum and x is 0.2, the absorbing frequency of the electromagnetic wave absorbing material is 182 GHz; when M is yttrium and x is 0.2, the absorbing frequency of the electromagnetic wave absorbing material is 179 GHz; when M is titanium and x is 0.2, the absorbing frequency of the electromagnetic wave absorbing material is 164 GHz; when M is silver and x is 0.2, the absorbing frequency of the electromagnetic wave absorbing material is 183 GHz; when M is aluminum and x is 0.1, the absorbing frequency of the electromagnetic wave absorbing material is 168 GHz; when M is aluminum and x is 0.2, the absorbing frequency of the electromagnetic wave absorbing material is 161 GHz; when M is aluminum and x is 0.4, the absorbing frequency of the electromagnetic wave absorbing material is 132 GHz; when M is aluminum and nickel and x is respective 0.3 and 0.1, the absorbing frequency of the electromagnetic wave absorbing material is 105 GHz.

In the present disclosure, the “shell layer” covers the core. Its function is to regulate the free energy of the core material, such that the crystal phase of the core material is stable in a metastable high-frequency absorbing crystal phase. In an embodiment, the composition of the shell layer includes an inorganic compound selected from oxides, nitrides, or combinations thereof. In another embodiment, the inorganic compound is at least one selected from a group consisting of silicon oxide, zirconium oxide, vanadium oxide, boron nitride, and aluminum nitride.

In an embodiment, the shell layer in the electromagnetic wave absorbing material has a thickness of 1 to 50 nm. In other embodiments, the thickness of the shell layer can be but not limited to 1, 2, 5, 10, 15, 20, 25, 30, 35, 40, 45, or 50 nm.

The particle dimension of the electromagnetic wave absorbing material of the present disclosure can be adjusted according to needs, but not limited thereto.

Regarding the structural ratio of the electromagnetic wave absorbing material, the core accounts for 5 to 95 volume percent of the entire electromagnetic wave absorbing material, and the shell layer accounts for 5 to 95 volume percent of the entire electromagnetic wave absorbing material. In other embodiments, the core can account for 5, 15, 25, 35, 45, 55, 65, 75, 85, or 95 volume percent of the entire electromagnetic wave absorbing material; and the shell layer can account for 5, 15, 25, 35, 45, 55, 65, 75, 85, or 95 volume percent of the entire electromagnetic wave absorbing material, but not limited thereto.

On the other hand, the aforementioned shell layer has the function of regulating the thermal expansion of the entire electromagnetic wave absorbing material, and therefore the shell layer of the present disclosure has a second thermal expansion coefficient less than the first thermal expansion coefficient. In an embodiment, the second thermal expansion coefficient is less than 30 ppm/K; in another embodiment, the second thermal expansion coefficient is −50 to 30 ppm/K; in other embodiments, the second thermal expansion coefficient can be −40, −35, −30, −25, −20, −15, −10, −5, 0, 5, 10, 15, 20, or 25 ppm/K, but not limited thereto.

By means of the selection of the shell layer material, the electromagnetic wave absorbing material of the present disclosure can achieve excellent performances, such as high thermal conductivity, high resistance, and low thermal expansion, so as to be compatible with a silicon substrate or a gallium nitride substrate in the application of packaging or printed circuit board.

Herein, the “amorphous intermediate layer” is disposed between the core and the shell layer, which comprises the iron oxide diffused from the core and the inorganic compound diffused from the shell layer. In an embodiment, components in the amorphous intermediate layer have specific spatial distributions, wherein the concentration distribution of the iron oxide gradually decreases from the inside towards the outside of the electromagnetic wave absorbing material, more specifically, gradually decreasing from the inside of the core towards the shell layer. The concentration distribution of the inorganic compound in the amorphous intermediate layer gradually increases from the inside towards the outside of the electromagnetic wave absorbing material, more specifically, gradually increasing from the inside of the core towards the shell layer.

In addition, the type and ratio of materials of the core and the shell layer are related to free energy. With the appropriate material and ratio, the effect of lattice matching and stability of the core and the shell layer can be achieved. In an embodiment, when the inorganic compound comprises silicon oxide, a molar ratio of silicon/iron in the electromagnetic wave absorbing material is 0.04 to 12; in other embodiments, the molar ratio of silicon/iron in the electromagnetic wave absorbing material can be 0.04, 0.07, 1, 3, 5, 7, 10, or 12, but not limited thereto.

In another embodiment, when the inorganic compound comprises silicon oxide, a molar ratio of zirconium/iron in the electromagnetic wave absorbing material is 0.01 to 3; in other embodiments, the molar ratio of zirconium/iron in the electromagnetic wave absorbing material can be 0.01, 0.04, 0.07, 1, 1.5, 2, 2.5, or 3, but not limited thereto.

A manufacturing method of an electromagnetic wave absorbing material is further provided in the present disclosure, and the method comprises: providing a shell layer material precursor and a core material precursor; coating the core material precursor with the shell layer material precursor to form a combination; sintering the combination at a high temperature to form a core and a shell layer, wherein materials of the core and the shell layer diffuse with each other; and etching the shell layer.

In an embodiment, the core material precursor, in the present disclosure, can refer to a material to be subsequently formed as an iron oxide; and in another embodiment, the core material precursor is selected from iron-based salts, or at least one selected from iron-based salts and a group consisting of molybdenum-based, zirconium-based, magnesium-based, cerium-based, lanthanum-based, yttrium-based, titanium-based, silver-based, aluminum-based, gallium-based, barium-based, rhodium-based and nickel-based salts. In an embodiment, the salt is such as nitrates.

In an embodiment, the shell layer material precursor, in the present disclosure, can refer to a material to be subsequently formed as an oxide, a nitride, or a compound of the aforementioned combination; and in another embodiment, the shell layer material precursor is selected from a group consisting of alkoxysilanes, tungstates, and oxychlorides.

In an embodiment, regarding the step of coating the core material precursor with the shell layer material precursor to form a combination, it can be achieved by adding both the core material precursor and the shell layer material precursor into a solvent and mixing with an alkaline neutralizer and surfactant. Herein, a period for stirring and mixing can be 1 to 4 hours, the temperature can be 40 to 80° C. In an embodiment, the alkaline neutralizer is at least one selected from a group consisting of ammonia water (NH₄OH) and alcohol amines. In an embodiment, the surfactant is at least one selected from a group consisting of cetyltrimethylammonium bromide, double-chain ionic surfactants, anionic surfactants, cationic surfactants, and nonionic surfactants.

In an embodiment, the high temperature for the sintering process is 1000 to 1200° C. in a period of 1 to 2 hours.

An etching process is to make the electromagnetic wave absorbing material contact with a conventional etchant, so that the outmost layer of the shell layer is etched. In an embodiment, the thickness of the shell layer is reduced by etching, the etchant is NaOH aqueous solution, the temperature of the etching process is from room temperature (25° C.) to 80° C., and a period for the etching process is 4 to 12 hours. In an embodiment, the etching process is to soak the electromagnetic wave absorbing material into NaOH aqueous solution at 60° C. for 6 hours.

In an embodiment, a manufacturing method of an electromagnetic wave absorbing material of the present disclosure comprises forming an electromagnetic wave absorbing material with a three-layer structure, comprising a core, an amorphous intermediate layer, and a shell layer, wherein the amorphous intermediate layer is formed by diffusing the materials of the core and the shell layer with each other.

Additionally, a composite structure for suppressing electromagnetic interference is further provided in the present disclosure, and the composite structure comprises the aforementioned electromagnetic wave absorbing material, a functional filler, and a matrix.

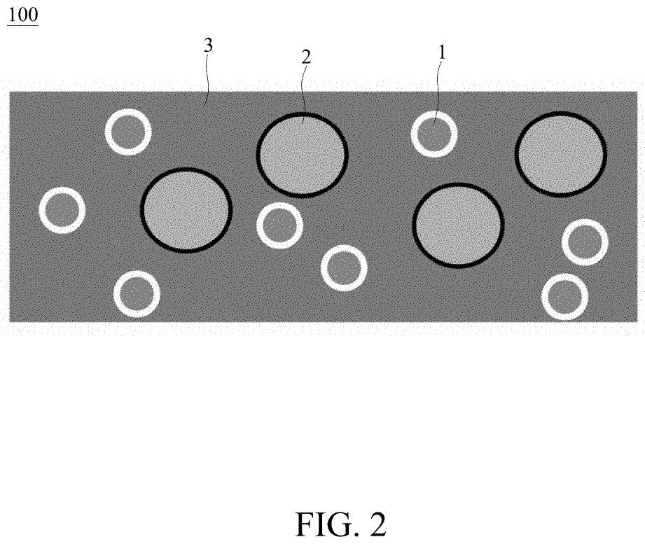

In an embodiment, referring to FIG. 2, a schematic structural diagram of a composite structure of the present disclosure, the composite structure 100 comprises an electromagnetic wave absorbing material 1, a functional filler 2, and a matrix 3.

Herein, the “functional filler” has characteristics of low dielectric, low thermal expansion, and high thermal conductivity, so it has functions of regulating the dielectric, thermal expansion, and thermal conductivity of the composite structure. In an embodiment, the material of the functional filler is the same as that of the shell layer in the electromagnetic wave absorbing material. In another embodiment, the functional filler comprises a material selected from silicon dioxide, boron nitride, aluminum nitride, silicon carbide, or a combination of the above. In a further embodiment, when the material of the functional filler is the same as that of the shell layer in the electromagnetic wave absorbing material, the material can be at least one compound selected from a group consisting of silicon dioxide, boron nitride, aluminum nitride, and silicon carbide.

Herein, the “matrix” is selected from epoxy resin, polypropylene resin, or polyimide resin, so that the electromagnetic wave absorbing material and the functional filler in the composite structure are evenly dispersed.

In the aforementioned composite structure, the electromagnetic wave absorbing material accounts for 5 to 95 volume percent of the entire composite structure, the functional filler accounts for greater than or equal to 5 volume percent of the entire composite structure, and the matrix accounts for greater than or equal to 5 volume percent of the entire composite structure.

In the present disclosure, by means of the design of the electromagnetic wave absorbing material and the selection of the functional filler, the following M.CAVILLON model is used:

$$α = {\sum }_{i} \frac{{α}_{i} {ρ}_{i} {x}_{i}}{ρ} , ρ = {\sum }_{i} {ρ}_{i} {x}_{i}$$

wherein a represents a thermal expansion coefficient, ρᵢ represents each material density, and xᵢ represents each material volume fraction. A composite structure with a thermal expansion coefficient of 0.5 to 93 ppm/K can be obtained. Therefore, when applied to a package or a printed circuit board, it can effectively suppress the electromagnetic interference problem.

According to the present disclosure, the iron oxide of the core has a magnetic moment capable of interacting with electromagnetic waves, so it provides an effect of absorbing high-frequency electromagnetic noise. In addition, the design of a core-shell structure can further be selective by materials of the shell layer and coefficients of thermal expansion, so as to adjust and stabilize the free energy of its core material, and to provide low dielectric, low thermal expansion, and high thermal conductivity. Hence, the electromagnetic wave absorbing material and the composite structure provided herein can address electromagnetic interference problems in the art, and also show extremely high industrial application value in the application of packaging material and printed circuit board technologies.

The present disclosure will be further described in detail through embodiments below, but will not be limited by embodiments illustrations.

### Example 1: Preparation of Electromagnetic Wave Absorbing Material

An electromagnetic wave absorbing material was prepared according to Process 1:

adding iron nitrate and tetraethoxysilane into 1500 g of 95% alcohol aqueous solution (the molar ratio of tetraethoxysilane/iron nitrate is 9.4), adding NH₄OH (the molar ratio of [NH₄OH]/[iron nitrate] was 28),
adding cetyltrimethylammonium bromide (the molar ratio of [cetyltrimethylammonium bromide]/[iron nitrate] was 2.75),
continuously stirring the solution with a mixer at 60° C. for 1 hour to mix evenly, filtering the mixed solution with filter paper, then drying it into powder in an oven at 90° C., and grinding the powder with a mortar, then sintering it at 1050° C. for 2 hours to obtain about 2 g of the final product.

According to powder X-ray diffraction analysis, the core of electromagnetic wave absorbing material is ε-Fe₂O₃, the shell layer is SiO₂, and the molar ratio of [Si]/[Fe] is 9.4. The performance of the electromagnetic wave absorbing material was analyzed by time domain spectrogram, and the measurement results of absorption frequency (FR) and shielding effectiveness (SE) were shown in Table 1.

### Example 1-1: Preparation of Electromagnetic Wave Absorbing-Material

Preparation was performed in the same manner as Process 1 of Example 1, except that: the molar ratio of [tetraethoxysilane]/[iron nitrate] was 0.44, the molar ratio of [NH₄OH]/[iron nitrate] was 28, and the molar ratio of [cetyltrimethylammonium bromide]/[iron nitrate] was 2.75. 2 g of the final product were obtained. According to powder X-ray diffraction analysis, the core of the electromagnetic wave absorbing material is ε-Fe₂O₃, the shell layer is SiO₂, and the molar ratio of [Si]/[Fe] is 0.44. The performance of the electromagnetic wave absorbing material was analyzed by time domain spectrogram, and the measurement results of absorption frequency (FR) and shielding effectiveness (SE) were shown in Table 1.

### Example 2: Preparation of Electromagnetic Wave Absorbing Material Doped with Elements

Preparation was performed in the same manner as Process 1 of Example 1, except that: ammonium paramolybdate was additionally added into the alcohol aqueous solution, the molar ratio of [tetraethoxysilane]/[iron nitrate] was 9.4, the molar ratio of [NH₄OH]/([iron nitrate]+[ammonium paramolybdate]) was 28, and the molar ratio of [cetyltrimethylammonium bromide]/([iron nitrate]/[ammonium paramolybdate]) was 2.75. 2 g of the final product were obtained. According to powder X-ray diffraction analysis, the core of the electromagnetic wave absorbing material is ε-Fe_{1.8}Mo_{0.2}O₃, the shell layer is Sift, and the molar ratio of [Si]/[Fe+Mo] is 9.4. The performance of the electromagnetic wave absorbing material was analyzed by time domain spectrogram, and the measurement results of absorption frequency (FR) and shielding effectiveness (SE) were shown in Table 1.

### Example 3: Preparation of Electromagnetic Wave Absorbing Material Doped with Elements

Preparation was performed in the same manner as Process 1 of Example 1, except that: zirconium oxychloride was additionally added into the alcohol aqueous solution, the molar ratio of [tetraethoxysilane]/([iron nitrate]+[zirconium oxychloride]) was 9.4, the molar ratio of [NH₄OH]/([iron nitrate]+[zirconium oxychloride]) was 28, and the molar ratio of [cetyltrimethylammonium bromide]/([iron nitrate]/[zirconium oxychloride]) was 2.75. 2 g of the final product were obtained. According to powder X-ray diffraction analysis, the core of the electromagnetic wave absorbing material is ε-Fe_{1.8}Zr_{0.2}O₃, the shell layer is Sift, and the molar ratio of [Si]/[Fe+Zr] is 9.4. The performance of the electromagnetic wave absorbing material was analyzed by time domain spectrogram, and the measurement results of absorption frequency (FR) and shielding effectiveness (SE) were shown in Table 1.

### Examples 4 to 9: Preparation of Electromagnetic Wave Absorbing Material Doped with M Elements

Preparation was performed in the same manner as Process 1 of Example 1, except that: M nitrate (wherein M was Mg, Ce, La, Y, Ti, Ag, respectively) was additionally added into the alcohol aqueous solution, the molar ratio of [tetraethoxysilane]/[iron nitrate]+[M nitrate] was 9.4, the molar ratio of [NH₄OH]/([iron nitrate]+[M nitrate]) was 28, and the molar ratio of [cetyltrimethylammonium bromide]/([iron nitrate]/[M nitrate]) was 2.75. 2 g of the final product were obtained in each example. According to powder X-ray diffraction analysis, the core of the electromagnetic wave absorbing material is ε-Fe_{1.8}M_{0.2}O₃, the shell layer is SiO₂, and the molar ratio of [Si]/[Fe+M] is 9.4. The performance of the electromagnetic wave absorbing material was analyzed by time domain spectrogram, and measurement results of absorption frequency (FR) and shielding effectiveness (SE) were shown in Table 1.

### Examples 10 to 12: Preparation of Electromagnetic Wave Absorbing Material Doped with M Elements

Preparation was performed in the same manner as Process 1 of Example 1, except that: aluminum nitrate was additionally added into the alcohol aqueous solution, the molar ratio of [tetraethoxysilane]/([iron nitrate]/[aluminum nitrate]) was 9.4, the molar ratio of [NH₄OH]/([iron nitrate]+[aluminum nitrate]) was 28, and the molar ratio of [cetyltrimethylammonium bromide]/([iron nitrate]+[aluminum nitrate]) was 2.75. 2 g of the final product were obtained. According to powder X-ray diffraction analysis, the core of the electromagnetic wave absorbing material is ε-Fe_{1.9}Al_{0.1}O₃, ε-Fe_{1.8}Al_{0.2}O₃, or ε-Fe_{1.6}Al_{0.4}O₃, respectively, the shell layer is all SiO₂, and the molar ratio of [Si]/[Fe+Al] is all 9.4. The performance of the electromagnetic wave absorbing material was analyzed by time domain spectrogram, and the measurement results of absorption frequency (FR) and shielding effectiveness (SE) were shown in Table 1.

### Example 13: Preparation of Electromagnetic Wave Absorbing Material Doped with M Elements

Preparation was performed in the same manner as Process 1 of Example 1, except that: aluminum nitrate and nickel nitrate were additionally added into the alcohol aqueous solution, the molar ratio of [tetraethoxysilane]/([iron nitrate]/[aluminum nitrate]+[nickel nitrate]) was 9.4, the molar ratio of [NH₄OH]/([iron nitrate]+[aluminum nitrate]+[nickel nitrate]) was 28, and the molar ratio of [cetyltrimethylammonium bromide]/([iron nitrate]+[aluminum nitrate]+[nickel nitrate]) was 2.75. 2 g of the final product were obtained. According to powder X-ray diffraction analysis, the core of the electromagnetic wave absorbing material is ε-Fe_{1.6}Al_{0.3}Ni_{0.1}O₃, the shell layer is Sift, and the molar ratio of [Si]/[Fe+Al+Ni] is 9.4. The performance of the electromagnetic wave absorbing material was analyzed by time domain spectrogram, and the measurement results of absorption frequency (FR) and shielding effectiveness (SE) were shown in Table 1.

### Examples 14 and 15: Preparation of Electromagnetic Wave Absorbing Material Doped with M Elements

Preparation was performed in the same manner as Process 1 of Example 1, except that: tetraethoxysilane was not added and zirconium oxychloride and sodium tungstate were additionally added into the alcohol aqueous solution instead, the molar ratio of [zirconium oxychloride]/[iron nitrate] was 0.1 and 0.67 respectively, the molar ratio of [NH₄OH]/[iron nitrate] was both 28, and the molar ratio of [cetyltrimethylammonium bromide]/[iron nitrate] was both 2.75. 2 g of the final product were obtained in each example. According to powder X-ray diffraction analysis, the core of the electromagnetic wave absorbing material is both ε-Fe₂O₃, the shell layer is both ZrW₂O₈, and the molar ratio of [Zr]/[Fe] is 0.1 and 0.67 respectively. The performance of the electromagnetic wave absorbing material was analyzed by time domain spectrogram, and the measurement results of absorption frequency (FR) and shielding effectiveness (SE) were shown in Table 1.

### Comparative Example 1

Preparation was performed according to Process 2:

adding 151.73 g of iron nitrate and 58.61 g of tetraethoxysilane into 1500 g of 95% alcohol aqueous solution,
continuously stirring all materials with a mixer at 25° C. for 3 hours to mix evenly, filtering the mixed solution with filter paper, waiting for 24 hours, then drying it into powder in an oven at 90° C., and
grinding the powder with a mortar, then sintering it at 1050° C. for 2 hours to obtain about 2 g of the final product.
According to powder X-ray diffraction analysis, the core of the composite material is α-Fe₂O₃, and the molar ratio of [Si]/[Fe] is 0.75. The performance of the composite material was analyzed by time domain spectrogram, and the measurement results of absorption frequency (FR) and shielding effectiveness (SE) were shown in Table 1.

### Comparative Example 2

Preparation was performed according to Process 3:

adding 101.15 g of iron nitrate, 31.29 g of NaOH, and 79.87 g of tetraethoxysilane into 1500 g of 95% alcohol aqueous solution,
mixing all materials with a mixer, adjusting the pH value of the mixed solution to 10, then continuously stirring the mixed solution at 25° C. for 40 hours,
filtering the mixed solution with filter paper then drying it into powder in an oven at 90° C., and
grinding the powder with a mortar, then sintering at 1100° C. for 4 hours to obtain about 2 g of the final product.
According to powder X-ray diffraction analysis, the core of the composite material is α-Fe₂O₃, and the molar ratio of [Si]/[Fe] is 1.5. The performance of the composite material was analyzed by time domain spectrogram, and the measurement results of absorption frequency (FR) and shielding effectiveness (SE) were shown in Table 1.

### Comparative Example 3

Preparation was performed according to Process 4:

adding 101.15 g of iron nitrate, 31.29 g of NaOH, 37.13 g of cetyltrimethylammonium bromide, 40.15 g of 1-butanol, 176.66 g of octane, and 79.87 g of tetraethoxysilane into 1500 g of 95% alcohol aqueous solution,
mixing all materials with a mixer, adjusting the pH value of the mixed solution to 14, then continuously stirring at 25° C. for 0.5 hours, adjusting the pH value again to 2, then stirring the mixed solution at 25° C. for 0.5 hours,
filtering the mixed solution with filter paper then drying it into powder in an oven at 90° C., and
grinding the powder with a mortar, then sintering it at 1100° C. for 4 hours to obtain about 2 g of the final product.
According to powder X-ray diffraction analysis, the core of the electromagnetic wave absorbing material is α-Fe₂O₃, the shell layer is Sift, and the molar ratio of [Si]/[Fe] is 1.5. The performance of the electromagnetic wave absorbing material was analyzed by time domain spectrogram, and the measurement results of absorption frequency (FR) and shielding effectiveness (SE) were shown in Table 1.

### Comparative Example 4

Preparation was performed in the same manner as Process 4 of Comparative Example 3, except that: 87.23 g of iron nitrate, 33.46 g of NaOH, 11.81 g of cetyltrimethylammonium bromide, 39.91 g of 1-butanol, 175.61 g of octane, 11.50 g of aluminum nitrate, and 79.87 g of tetraethoxysilane was added into the alcohol aqueous solution. About 2 g of the final product were obtained. According to powder X-ray diffraction analysis, the core of the electromagnetic wave absorbing material is α-Fe_{1.6}Al_{0.4}O₃, the shell layer is SiO₂, and the molar ratio of [Si]/[Fe+Al] is 1.5. The performance of the electromagnetic wave absorbing material was analyzed by time domain spectrogram, and the measurement results of absorption frequency (FR) and shielding effectiveness (SE) were shown in Table 1.

TABLE 1

| | Electromagnetic wave | Molar ratio of | | |
|---|---|---|---|---|
| | absorbing material | [Si]/[Fe + M elements] | F_{R}(GHz) | SE(dB) |
| Example 1 | ε-Fe₂O₃/SiO₂ | 9.4 | 181 | 22 |
| Example 1-1 | ε-Fe₂O₃/SiO₂ | 0.44 | none | none |
| Example 2 | ε-Fe_{1.8}Mo_{0.2}O₃/SiO₂ | 9.4 | 180 | 23 |
| Example 3 | ε-Fe_{1.8}Zr_{0.2}O₃/SiO₂ | 9.4 | 172 | 26 |
| Example 4 | ε-Fe_{1.8}Mg_{0.2}O₃/SiO₂ | 9.4 | 176 | 19 |
| Example 5 | ε-Fe_{1.8}Ce_{0.2}O₃/SiO₂ | 9.4 | 178 | 20 |
| Example 6 | ε-Fe_{1.8}La_{0.2}O₃/SiO₂ | 9.4 | 182 | 17 |
| Example 7 | ε-Fe_{1.8}Y_{0.2}O₃/SiO₂ | 9.4 | 179 | 18 |
| Example 8 | ε-Fe_{1.8}Ti_{0.2}O₃/SiO₂ | 9.4 | 164 | 8 |
| Example 9 | ε-Fe_{1.8}Ag_{0.2}O₃/SiO₂ | 9.4 | 183 | 13 |
| Example 10 | ε-Fe_{1.9}Al_{0.1}O₃/SiO₂ | 9.4 | 168 | 12.6 |
| Example 11 | ε-Fe_{1.8}Al_{0.2}O₃/SiO₂ | 9.4 | 161 | 11.4 |
| Example 12 | ε-Fe_{1.6}Al_{0.4}O₃/SiO₂ | 9.4 | 132 | 11.7 |
| Example 13 | ε-Fe_{1.6}Al_{0.3}Ni_{0.1}O₃/SiO₂ | 9.4 | 105 | 7.6 |

| | Electromagnetic wave | Molar ratio of | | |
|---|---|---|---|---|
| | absorbing material | [Zr]/[Fe + M elements] | F_{R}(GHz) | SE(dB) |
| Example 14 | ε-Fe₂O₃/ZrW₂O₈ | 0.1 | 358 | 35.5 |
| Example 15 | ε-Fe₂O₃/ZrW₂O₈ | 0.67 | 317 | 33 |

| | | Molar ratio of | | |
|---|---|---|---|---|
| | Product | [Si]/[Fe + M elements] | F_{R}(GHz) | SE(dB) |
| Comparative | α-Fe₂O₃/SiO₂ | 0.75 | Fail | Fail |
| Example 1 | | | | |
| Comparative | α-Fe₂O₃/SiO₂ | 1.5 | Fail | Fail |
| Example 2 | | | | |
| Comparative | α-Fe₂O₃/SiO₂ | 1.5 | Fail | Fail |
| Example 3 | | | | |
| Comparative | α-Fe_{1.6}Al_{0.4}O₃/SiO₂ | 1.5 | Fail | Fail |
| Example 4 | | | | |

*“Fail” means that there was no absorption frequency, no shielding effect was present and thus the sample cannot be used as a suitable electromagnetic wave absorbing material.

The electromagnetic wave absorbing material obtained by the aforementioned examples and comparative examples were performed in the following testing analysis:

Analytical methods are described as follows:

Powder X-ray diffraction analysis: the powder sample to be measured was filled in a carrier and fixed on an instrument detection platform, and measured by a powder X-ray diffractometer (PANalytical PW 3040) under operating conditions: a copper target, 2 theta Start/End angles: 10 to 60 degrees, and a Scan step size: 0.04 degrees, so as to measure X-ray diffraction patterns.

Time domain spectrogram analysis: a laser was used to excite a photoconductive antenna to generate an electromagnetic wave, which irritated the sample to be tested, and another photoconductive antenna was used to receive the radiation wave signal penetrating the sample. Shielding performances of the sample were obtained by calibration and conversion using an original sub-THz radiation spectrogram without samples. The aforementioned laser was Coherent Verdi V-6 Diode-Pumped solid Laser and was used to excite Ti: sapphire femtosecond laser kit of KMLabs company to produce pulsed laser and self-assembled femtosecond fiber laser.

Saturation magnetization analysis: a vibrating sample magnetometer (lakeshore MODEL 7304) was used to measure and analyze the relationship between the magnetic field and magnetization of the sample to obtain the saturation magnetization (Ms) characteristics of the sample.

Thermomechanical analysis: MA equipment (TA Q400) was used, and the coefficient of thermal expansion (CTE) of the sample was measured and analyzed according to the test method ASTM E831-05.

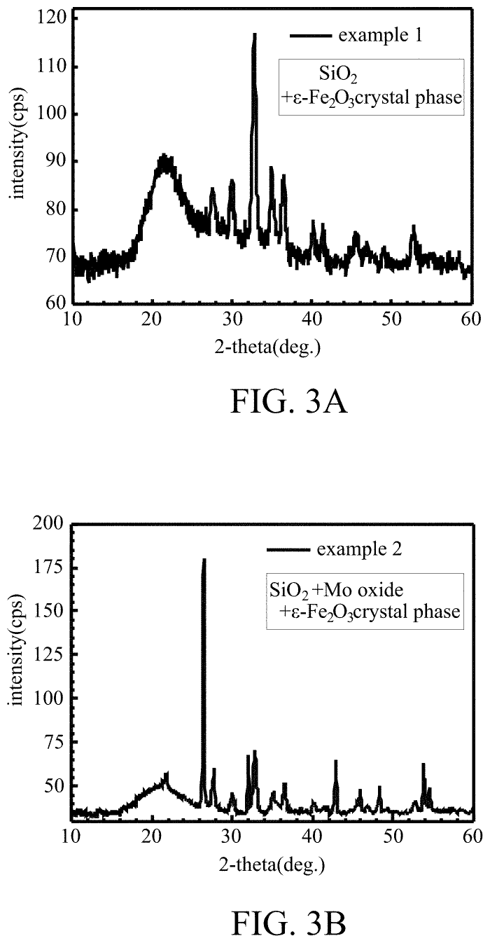

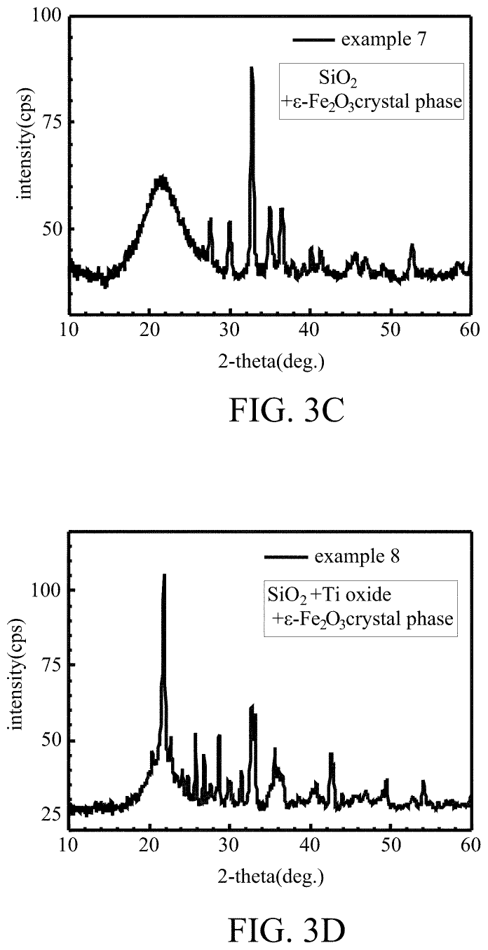

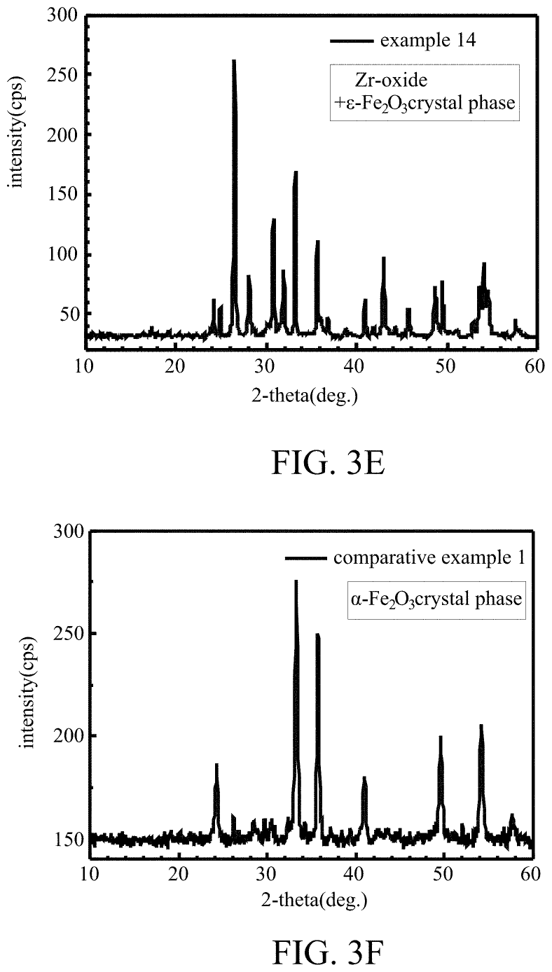

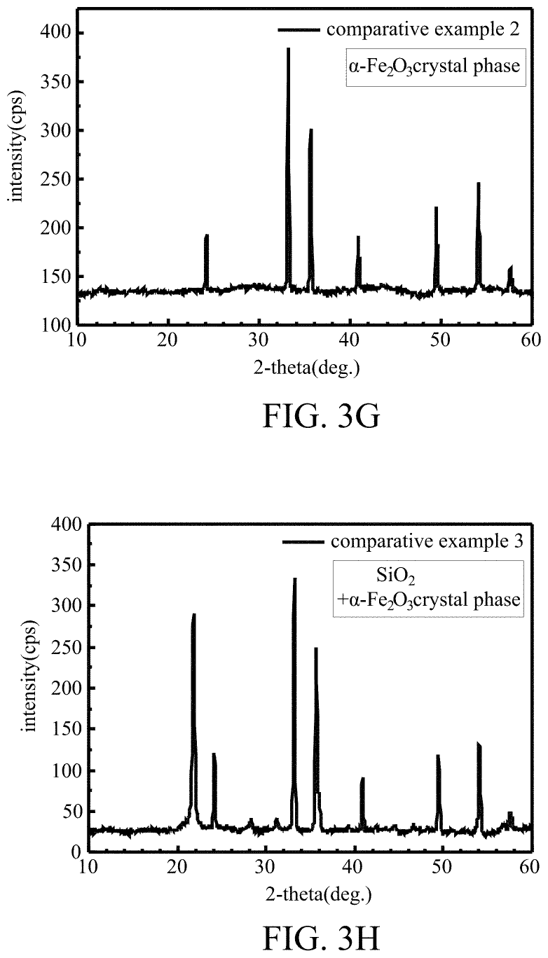

(1) X-ray diffraction analysis: results were shown in FIGS. 3A to 31.

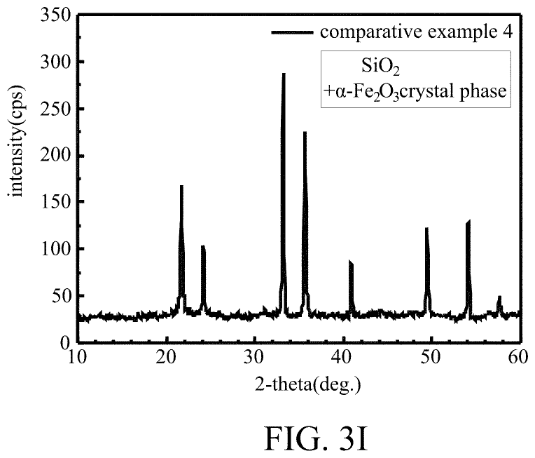

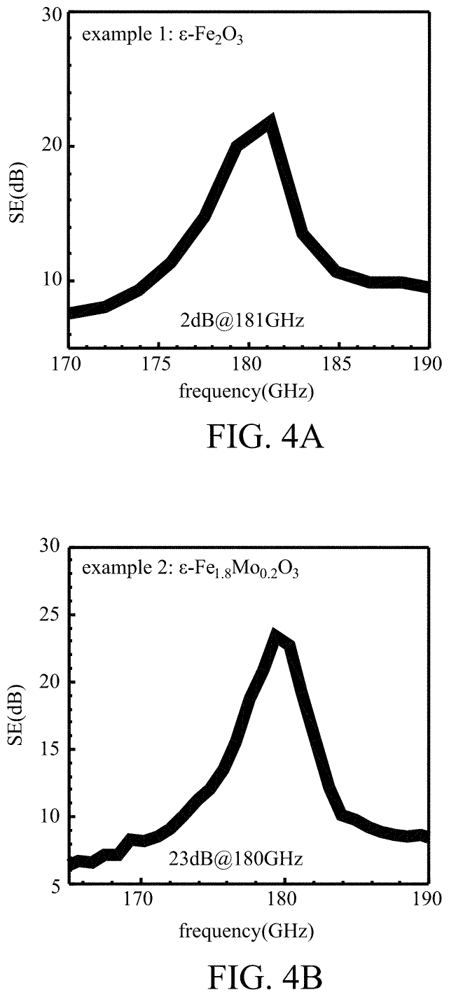

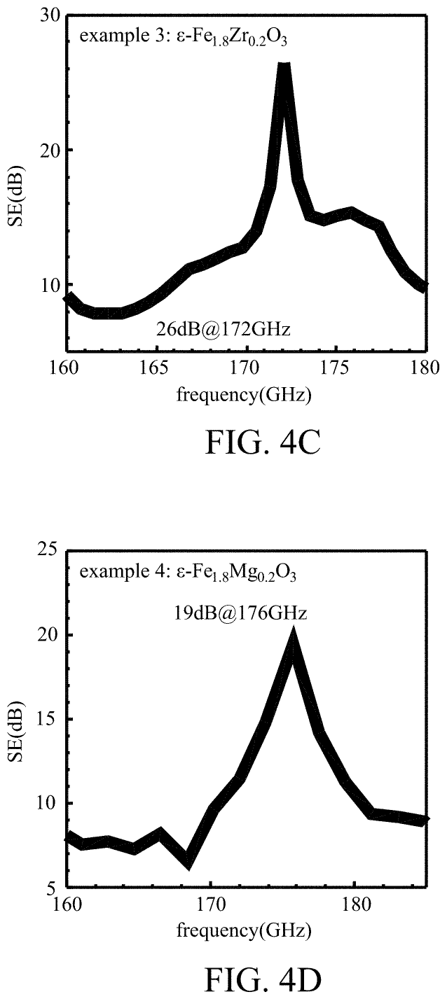

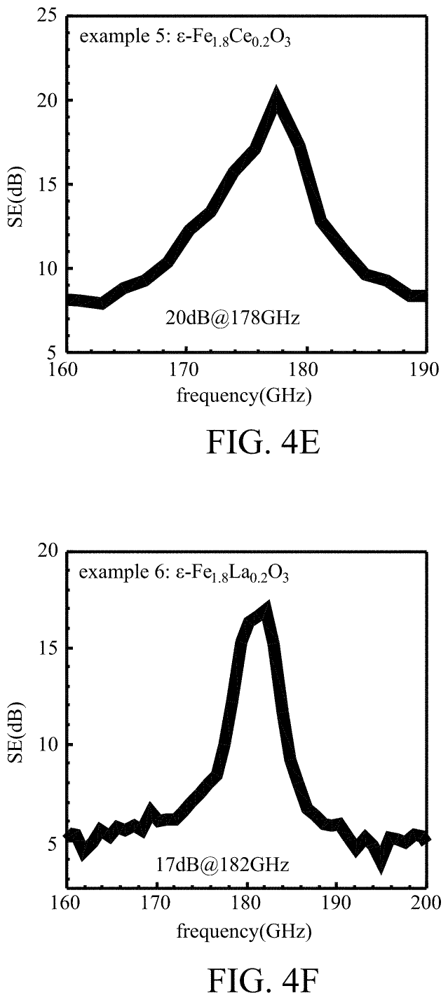

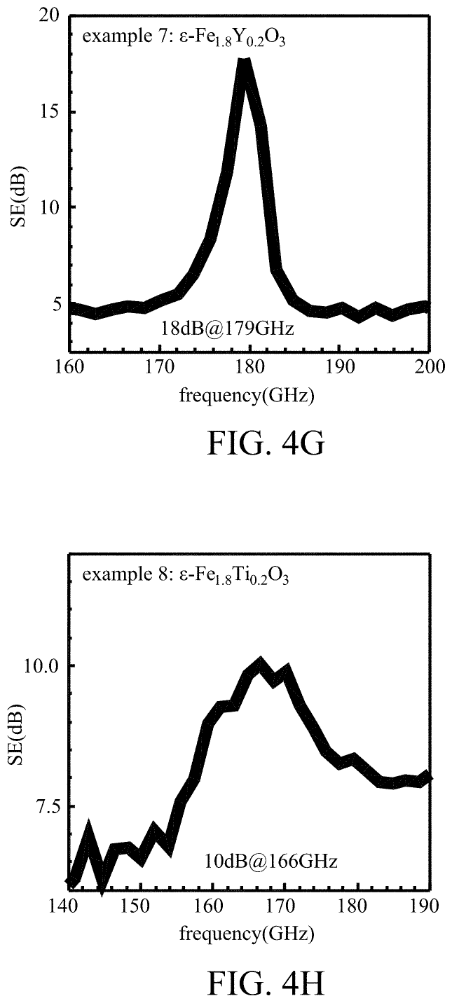

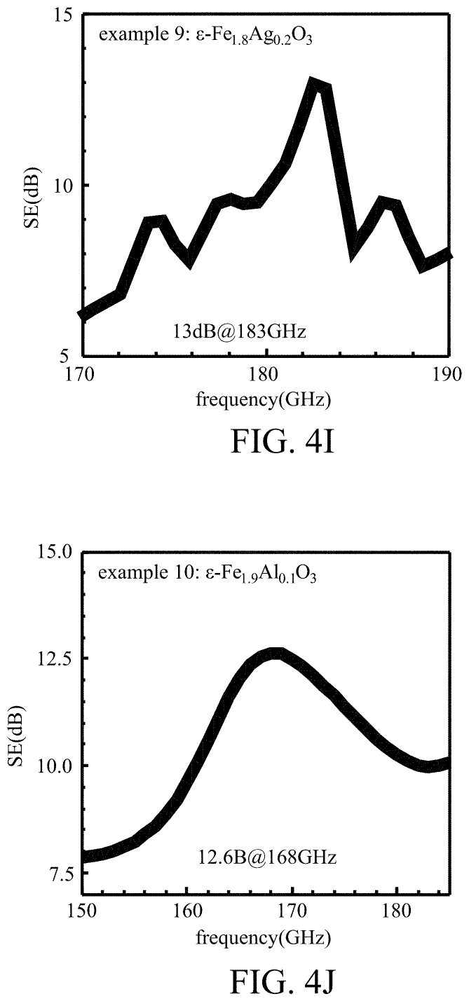

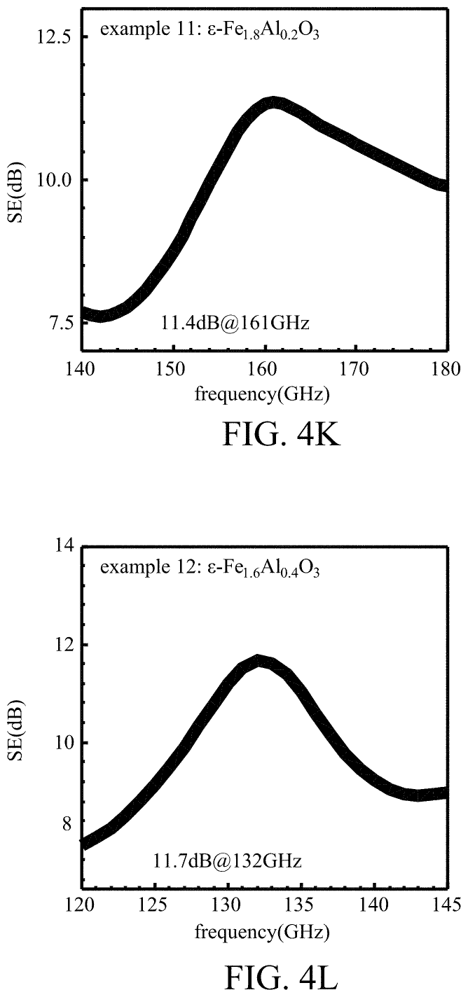

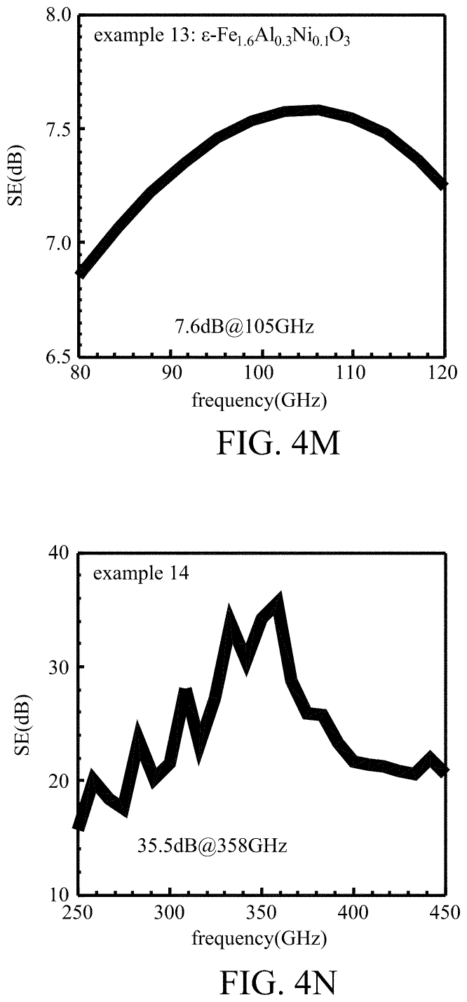

(2) Time domain spectrogram analysis: results were shown in FIGS. 4A to 4D and Table 1.

According to the X-ray diffraction analysis, the crystal form of iron oxide in the core of Comparative Examples 1 to 4 is rhombohedral (a form), and the shell layer is SiO₂, by comparing with the pattern database. There is no amorphous intermediate layer in Comparative Examples 1 to 4, so iron oxide in the core cannot form a metastable orthorhombic (c form) crystal form.

According to Examples 1 to 15 of Table 1 and X-ray diffraction analysis, by comparing with the pattern database, it was found that: in Examples 1 and 7, the crystal form of iron oxide in the core is orthorhombic (c form), and an amorphous intermediate layer and a SiO₂ shell layer is present; in Example 2, the crystal form of iron oxide in the core is orthorhombic (c form) and molybdenum oxide (Mo oxide), and an amorphous intermediate layer and a SiO₂ shell layer is present; in Example 8, the crystal form of iron oxide in the core is orthorhombic (c form) and titanium oxide (Ti oxide), and an amorphous intermediate layer and a SiO₂ shell layer is present; in Example 14, the crystal form of iron oxide in the core is orthorhombic (c form), and an amorphous intermediate layer and a zirconium oxide (Zr oxide) shell layer is present.

According to the crystal form diffraction results of the amorphous intermediate layer, the shell layer, and iron oxide in Examples 1 to 15 of Table 1, it can be known that the electromagnetic wave absorbing materials of Examples 1 to 15 have better lattice matching due to the suitable ratio and manufacturing process of the core-shell structure and the existence of the amorphous intermediate layer. By adjusting the free energy of the core, its iron oxide formed stably an orthorhombic system (c form).

The performances of the electromagnetic wave absorbing materials were analyzed by time domain spectrogram, and the measurement results of absorption frequency of material (FR) and shielding effectiveness (SE) were listed in Table 1. When M is molybdenum and x is 0.2, the absorption frequency of the electromagnetic wave absorbing material is 180 GHz; when M is zirconium and x is 0.2, the absorption frequency of the electromagnetic wave absorbing material is 172 GHz; when M is magnesium and x is 0.2, the absorption frequency of the electromagnetic wave absorbing material is 176 GHz; when M is cerium and x is 0.2, the absorption frequency of the electromagnetic wave absorbing material is 178 GHz; when M is lanthanum and x is 0.2, the absorption frequency of the electromagnetic wave absorbing material is 182 GHz; when M is yttrium and x is 0.2, the absorption frequency of the electromagnetic wave absorbing material is 179 GHz; when M is titanium and x is 0.2, the absorption frequency of the electromagnetic wave absorbing material is 164 GHz; when M is silver and x is 0.2, the absorption frequency of the electromagnetic wave absorbing material is 183 GHz; when M is aluminum and x is 0.1, the absorption frequency of the electromagnetic wave absorbing material is 168 GHz; when M is aluminum and x is 0.2, the absorption frequency of the electromagnetic wave absorbing material is 161 GHz; when M is aluminum and x is 0.4, the absorption frequency of the electromagnetic wave absorbing material is 132 GHz; when M is aluminum and nickel and x is 0.3 and 0.1 respectively, the absorption frequency of the electromagnetic wave absorbing material is 105 GHz. From the above results, the core of the electromagnetic wave absorbing material of the present disclosure can form stable orthorhombic (c form) iron oxide and have a high-frequency electromagnetic wave absorption function, and the absorption frequency of the magnetic wave absorbing material can be adjusted by doping elements to allow the material to have a boarder application filed.

Preparation of Electromagnetic Wave Absorbing Material of Examples 16 to 20

1 g of produced electromagnetic absorbing materials according to examples 1, 2, 5, 6, and 11 respectively was put into 200 ml of 5M NaOH aqueous solution for 14 hours to etch the shell layer, and then said etched electromagnetic absorbing materials were dried in an oven at 90° C. to obtain the electromagnetic absorbing material with a thin shell layer.

The above obtained electromagnetic wave absorbing materials were tested and analyzed as follows:

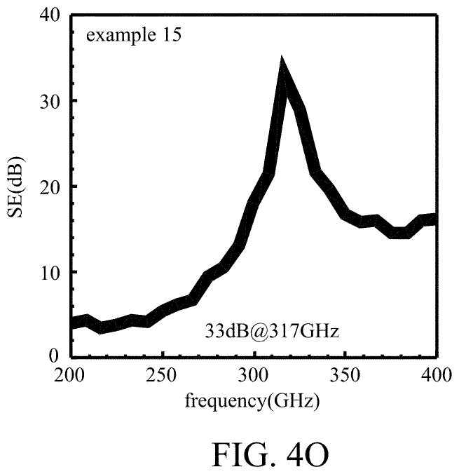

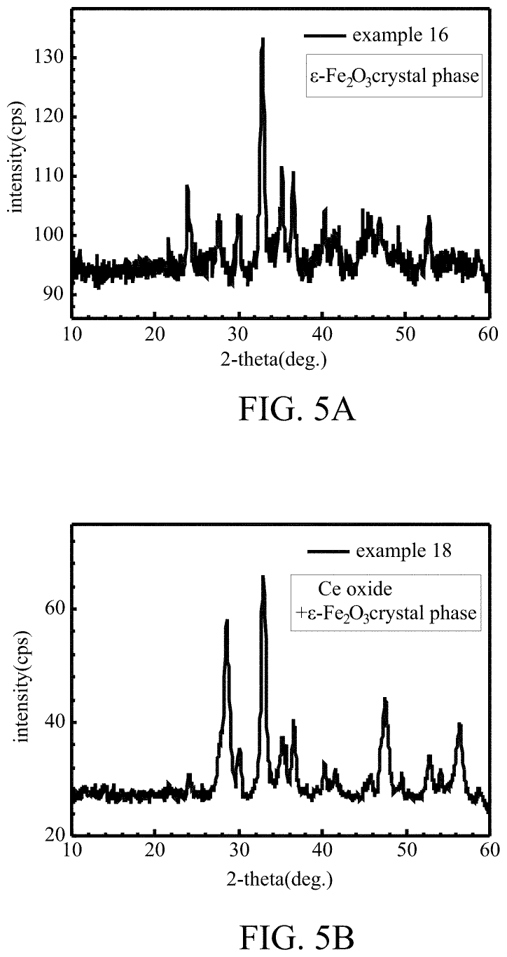

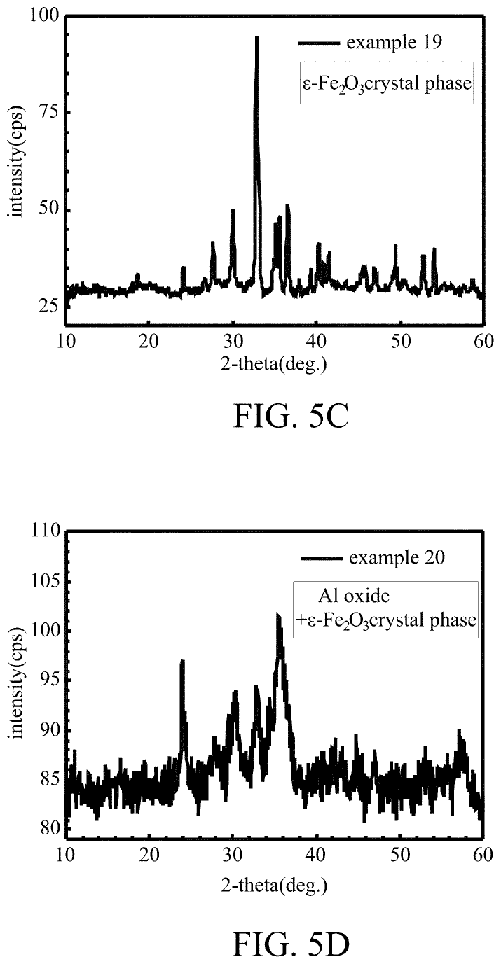

(1) X-ray diffraction analysis: results were shown in FIGS. 5A to 5D.

(2) Saturation magnetization analysis: results were shown in FIG. 2.

TABLE 2

| | Electromagnetic wave | Saturation |
|---|---|---|
| | absorbing material | magnetization (emu/g) |
| Example 16 | ε-Fe2O3/SiO₂ of thin shell layer | 2.03 |
| Example 17 | ε-Fe_{1.8}Mo_{0.2}O₃/SiO₂ of thin shell layer | 3.4 |
| Example 18 | ε-Fe_{1.8}Ce_{0.2}O₃/SiO₂ of thin shell layer | 2.43 |
| Example 19 | ε-Fe_{1.8}La_{0.2}O₃/SiO₂ of thin shell layer | 1.2 |
| Example 20 | ε-Fe_{1.8}Al_{0.2}O₃/SiO₂ of thin shell layer | 3.2 |

According to X-ray diffraction pattern analysis, most of the shell layers were removed by etching and became thin shell layers. The magnetization characteristics of the material were analyzed by a vibrating magnetometer system, and the saturation magnetization results were listed in Table 2. The data showed that the magnetic moment coupling is altered by doping elements in the core ε-Fe₂O₃, and thereby the saturation magnetization characteristics are further adjustable.

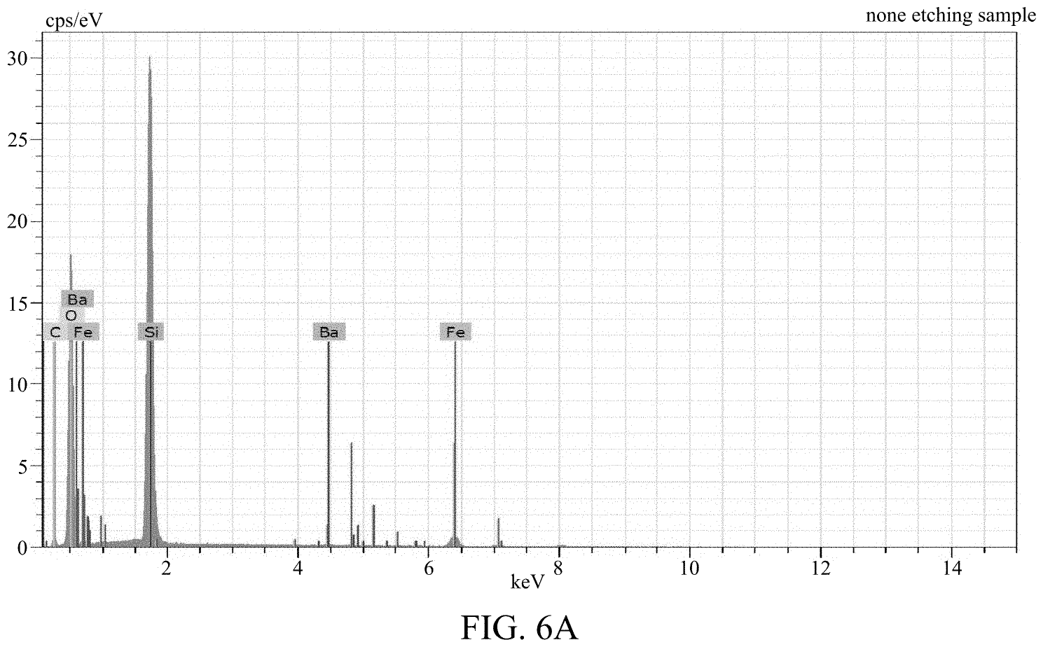

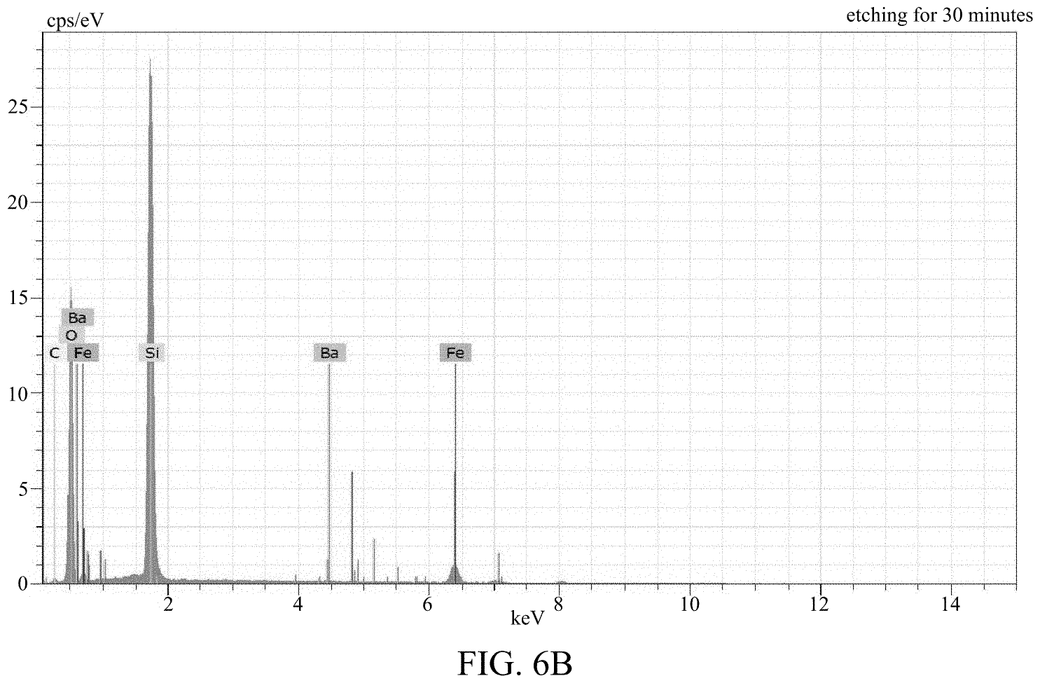

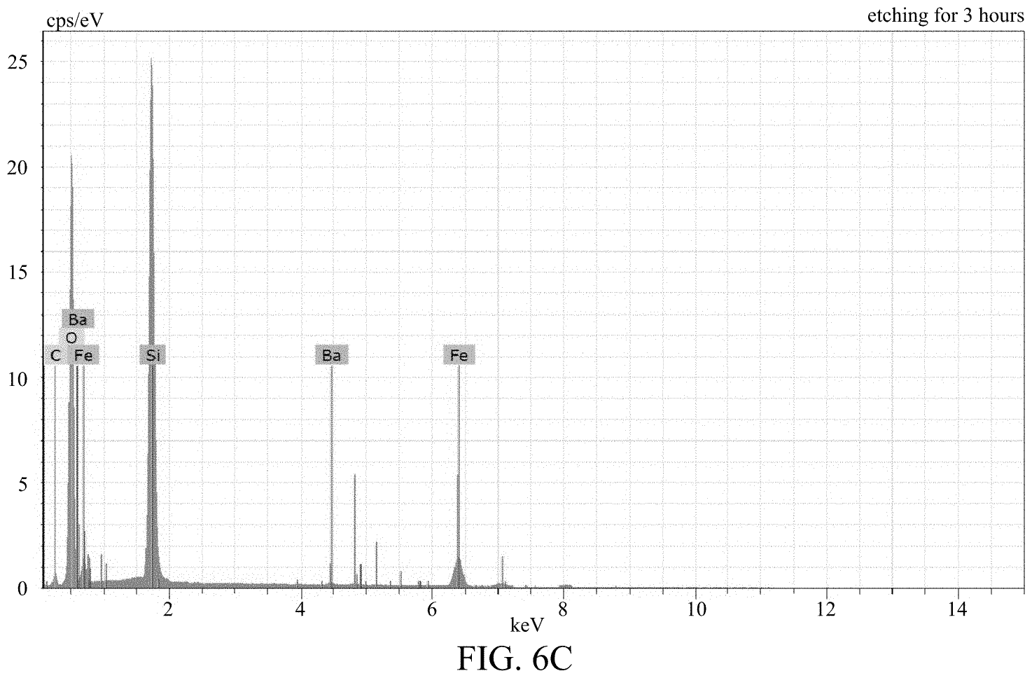

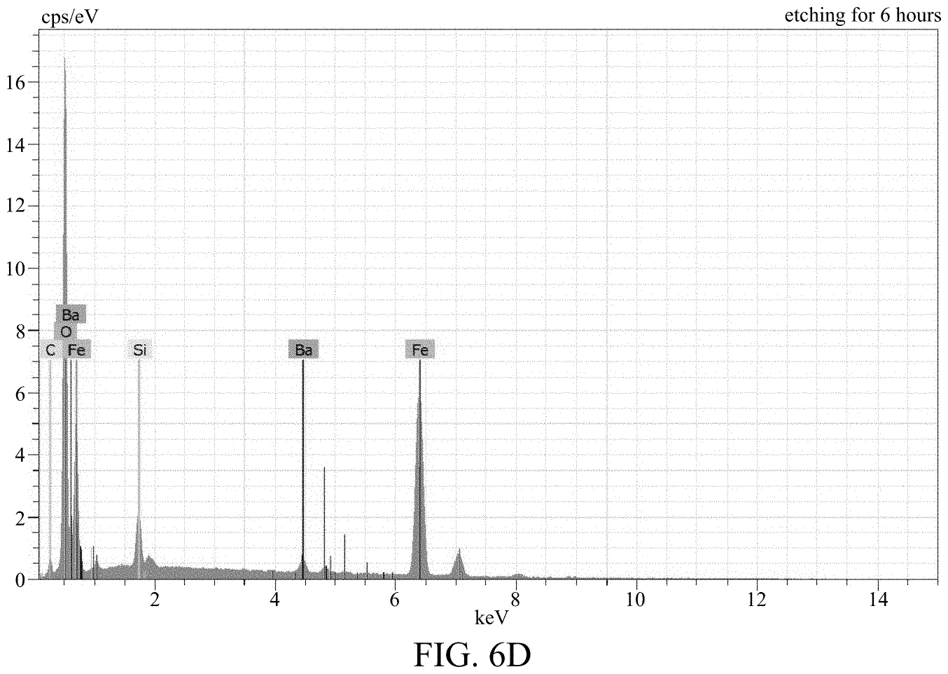

Examples 16-1 to 16-3 were prepared in the same manner as Example 16, except that: the electromagnetic wave absorbing material was placed in an ultrasonic cleaning tank equipped with 5M NaOH aqueous solution for 30 minutes, 3 hours, and 6 hours respectively, and energy dispersive X-ray spectroscopy (EDS) analysis was performed on the electromagnetic wave absorbing materials of Example 1 and Examples 16-1 to 16-3. The results were shown in Table 3 and FIGS. 6A to 6D.

TABLE 3

| | | | Measured | Standardization | | | Weight | Molar |
|---|---|---|---|---|---|---|---|---|
| | Atomic | | element | element | Standardization | weight % | ratio of | ratio of |
| | number | system | weight % | weight % | atomic % | deviation | [Si]/[Fe] | [Si]/[Fe] |
| Example 1 | | | | | | | | |
| none | | | | | | | | |
| etching | | | | | | | | |
| C | 6 | K | 5.44 | 5.54 | 9.28 | 1.12 | 5.02 | 99.88 |
| O | 8 | K | 47.79 | 48.74 | 61.25 | 5.62 | | |
| Si | 14 | K | 36.5 | 37.22 | 26.65 | 1.55 | | |
| Fe | 26 | K | 7.26 | 7.41 | 2.67 | 0.27 | | |
| Ba | 56 | L | 1.06 | 1.08 | 0.16 | 0.07 | | |
| Total | | | 98.05 | 100.00 | 100.00 | | | |
| Example 16-1 | | | | | | | | |
| etching for | | | | | | | | |
| 30 minutes | | | | | | | | |
| C | 6 | K | 3.20 | 3.37 | 5.93 | 0.85 | 3.57 | 7.095 |
| O | 8 | K | 43.57 | 45.98 | 60.69 | 5.29 | | |
| Si | 14 | K | 36.69 | 38.72 | 29.11 | 1.56 | | |
| Fe | 26 | K | 10.29 | 10.86 | 4.11 | 0.37 | | |
| Ba | 56 | L | 1.01 | 1.07 | 0.16 | 0.08 | | |
| Total | | | 94.76 | 100.00 | 100.00 | | | |
| Example 16-2 | | | | | | | | |
| etching for | | | | | | | | |
| 3 hours | | | | | | | | |
| C | 6 | K | 5.36 | 5.37 | 9.25 | 1.05 | 2.09 | 4.15 |
| O | 8 | K | 48.84 | 48.92 | 63.27 | 5.67 | | |
| Si | 14 | K | 29.78 | 29.83 | 21.98 | 1.27 | | |
| Fe | 26 | K | 14.10 | 14.13 | 5.23 | 0.47 | | |
| Ba | 56 | L | 1.75 | 1.76 | 0.26 | 0.09 | | |
| Total | | | 99.83 | 100.00 | 100.00 | | | |
| Example 16-3 | | | | | | | | |
| etching 6 | | | | | | | | |
| hours | | | | | | | | |
| C | 6 | K | 2.55 | 2.73 | 6.63 | 0.58 | 0.04 | 0.08 |
| O | 8 | K | 30.35 | 32.48 | 59.33 | 3.67 | | |
| Si | 14 | K | 2.28 | 2.44 | 2.54 | 0.13 | | |
| Fe | 26 | K | 54.84 | 58.70 | 30.72 | 1.66 | | |
| Ba | 56 | L | 3.42 | 3.66 | 0.78 | 0.14 | | |

| | | | |
|---|---|---|---|
| Total | 93.43 | 100.00 | 100.00 |

According to the results of XPS analysis, the SiO₂ shell layer of the electromagnetic wave absorbing material can be etched by NaOH aqueous solution, wherein the sample without etching of Example 1 showed that the weight ratio of Si/Fe is about 5.02, and molar ratio of [Si]/[Fe] is about 9.88; the sample with about 30 minutes of etching of Example 16-1 showed that weight ratio of Si/Fe is about 3.57, and molar ratio of [Si]/[Fe] is about 7.09; the sample with about 3 hours of etching of Example 16-2 showed that weight ratio of Si/Fe is about 2.09, and molar ratio of [Si]/[Fe] is about 4.15; the sample with about 6 hours of etching of Example 16-3 showed that weight ratio of Si/Fe is about 0.04, and molar ratio of [Si]/[Fe] is about 0.08.

### Examples 21 to 24: Preparation of Composite Structure

Process 5: according to the formulation of the electromagnetic wave absorbing material, the SiO₂ functional filler and the epoxy resin matrix shown in the following Table 4, the materials were evenly mixed with acetone, granulated, sieved with a 40 mesh screen to obtain composite powder. 0.9 g of the composite powder was put into a Ψ 7.2 mm mold and pressed at a gauge pressure of 20 bar. The molded sample was placed in an oven at 95° C. for 1 hour, and then the temperature was raised to 165° C. for 1 hour to obtain the composite structure of Examples 21 to 24, for time domain spectrogram analysis.

### Comparative Example 5: Composite Structure of None Electromagnetic Wave Absorbing Material

According to Process 5 and the formulation of the SiO₂ functional filler and the epoxy resin matrix shown in the following Table 4, the materials were used to prepare the composite structure of Comparative Example 5 for time domain spectrogram analysis.

The above obtained electromagnetic wave absorbing materials were tested and analyzed as follows:

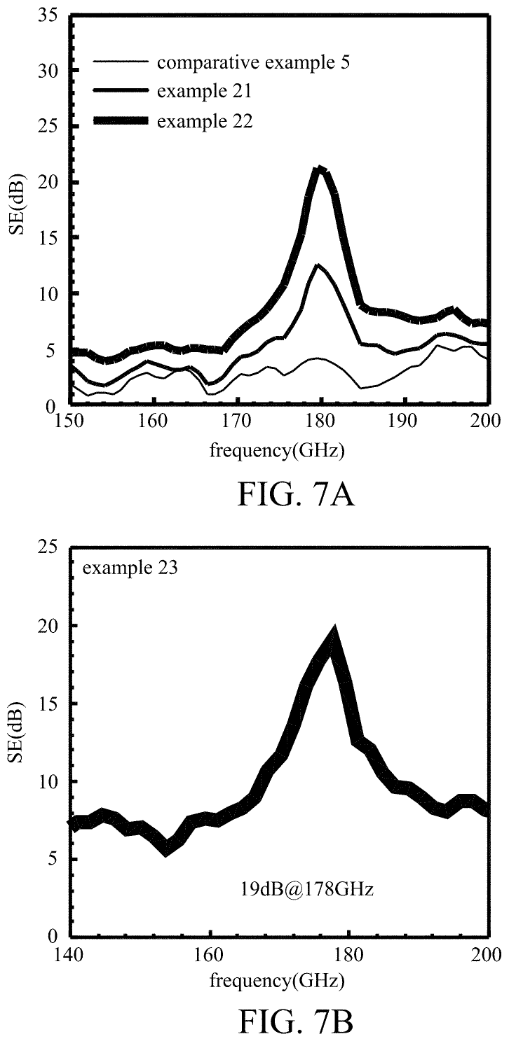

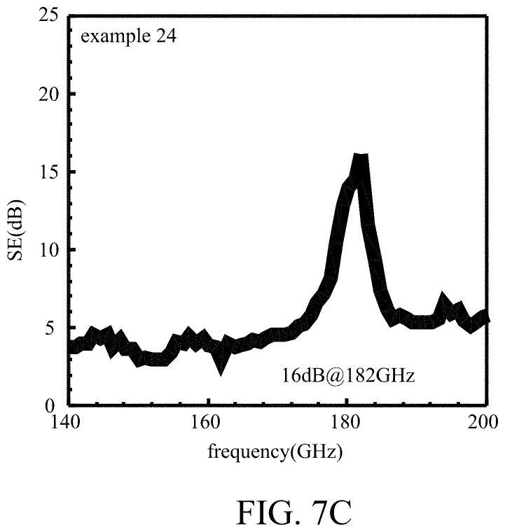

Time domain spectrogram analysis: results were shown in Table 4 and FIGS. 7A to 7C.

TABLE 4

| | | Ratio of | | | | |
|---|---|---|---|---|---|---|
| | | electromagnetic | | | | |
| | Electromagnetic | wave absorbing | | | | |
| | wave absorbing | material | SiO₂ | matrix | F_{R} | SE@F_{R} |
| | material | (volume %) | (volume %) | (volume %) | (GHz) | (dB) |
| Example 21 | Example 16 | 8 | 52 | 40 | 180 | 13 |
| Example 22 | Example 16 | 18 | 38 | 44 | 180 | 21 |
| Example 23 | Example 18 | 18 | 38 | 44 | 178 | 19 |
| Example 24 | Example 19 | 18 | 38 | 44 | 182 | 16 |
| Comparative | None | 0 | 62 | 38 | none | none |
| example 5 | | | | | | |

The performances of the electromagnetic wave absorbing materials analyzed by time domain spectrogram of Examples 21 to 24 and Comparative Example 5, the measurement results of absorption frequency (FR) and shielding effectiveness (SE) were listed in Table 4. The data showed that the addition of the electromagnetic wave absorbing material in Examples 21 to 22 resulted in absorption frequency (FR) at 180 GHz; and shielding effectiveness (SE) of the composite structure with 8 volume % of the electromagnetic wave absorbing material is 13 dB, and improves to 21 dB with 18 volume % of the electromagnetic wave absorbing material, indicating that the more electromagnetic wave absorbing material, the better shielding effectiveness. In addition, it can be seen that the composite material without the electromagnetic wave absorbing material shows no electromagnetic wave absorption performance, while that added with the electromagnetic wave absorbing material has electromagnetic wave absorption performance.

### Examples 25 to 27: Preparation of Composite Structure

Process 6: according to the formulation of the electromagnetic wave absorbing material, the Sift functional filler and the epoxy resin matrix shown in the following Table 5, the materials were evenly mixed with acetone, granulated, sieved with a 40 mesh screen to obtain composite powder. 0.13 g of the composite powder was put into a Ψ 4 mm mold and pressed at a gauge pressure of 20 bar. The molded sample was placed in an oven at 95° C. for 1 hour, and then the temperature was raised to 165° C. for 1 hour to obtain the composite structure of Examples 25 to 27, for thermomechanical analysis.

Then, the above obtained electromagnetic wave absorbing materials were tested and analyzed as follows:

Thermomechanical Analysis:

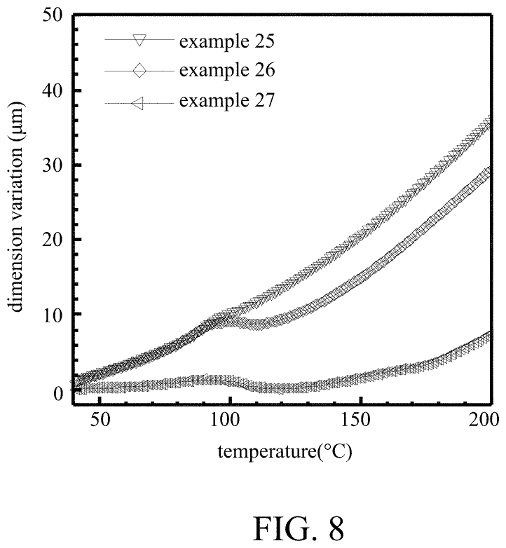

Thermomechanical analysis results were listed in Table 5, and the CTE measured value (21.6 ppm/K) and Sift theoretical CTE value (0.5 ppm/K) of the composite material of Example 25 were brought into M.CAVILLON model, and the CTE of the matrix was obtained as 93 ppm/K (as shown in FIG. 6). Then the CTE value of the matrix, Example 26 (19.8 ppm/K) and Example 27 (5.4 ppm/K) were brought into M.CAVILLON model, the CTE values of Example 1-1 and Example 14 were obtained as 3 ppm/K and −11 ppm/K, respectively. In addition, as shown in FIG. 8, dimensional variations of the composite structures of Examples 26 and 27 were small. According to the above analysis, the technical solution of the present disclosure can adjust the CTE value of the electromagnetic wave absorbing material through the material of the shell layer, and this characteristic can be used in industries that require the CTE value of the two media to match with each other, such as packaging-related industries.

TABLE 5

| | | Electromagnetic | | | CTE |
|---|---|---|---|---|---|
| | | wave absorbing | | | measured |
| | Original | material | SiO₂ | matrix | value |
| | material | (volume %) | (volume %) | (volume %) | (ppm/K) |
| Example 25 | none | 0 | 62 | 38 | 21.6 |
| Example 26 | Example 1-1 | 15 | 41 | 44 | 19.8 |
| Example 27 | Example 14 | 22 | 43 | 35 | 5.4 |

TABLE 6

| | CTE(ppm/K) | | |
|---|---|---|---|
| | SiO₂ | matrix | Electromagnetic wave |
| | (theoretical | (estimated | absorbing material |
| | value) | value) | (estimated value) |
| Example 25 | 0.5 | 93 | none |
| Example 26 | 0.5 | 93 | 3 |
| Example 27 | 0.5 | 93 | −11 |

To sum up, the electromagnetic wave absorbing material of the present disclosure has iron oxide in the core, which endows this material with a magnetic moment interacting with electromagnetic waves, so as to provide the effect of absorbing high-frequency electromagnetic noise. Furthermore, the design of the core-shell structure, for example, comprising the selection of shell layer materials and coefficients of thermal expansion, can adjust and stabilize the free energy of its core material, and enable it to have properties such as low dielectric, low thermal expansion, and high thermal conductivity. Hence, the electromagnetic wave absorbing material and the composite structure provided by the present disclosure can address electromagnetic interference problems in the prior art, and also shows extremely high industrial application value in the application of packaging material and printed circuit board technologies.

The above embodiments and examples are set forth to illustrate the principles of the present disclosure and the effects thereof, and should not be interpreted as limiting the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electromagnetic wave absorbing material, comprising:
a core, wherein the core comprises an iron oxide and having a first thermal expansion coefficient; and
a shell layer, covering the core, wherein the shell layer has a second thermal expansion coefficient less than the first thermal expansion coefficient, and the shell layer comprises an inorganic compound selected from a group consisting of oxides, nitrides, or any combination thereof.

2. The electromagnetic wave absorbing material of claim 1, further comprises an amorphous intermediate layer disposed between the core and the shell layer, wherein the amorphous intermediate layer comprises the iron oxide diffused from the core and the inorganic compound diffused from the shell layer, the concentration distribution of the iron oxide gradually decreases from the inside towards the outside of the electromagnetic wave absorbing material, and the concentration distribution of the inorganic compound gradually increases from the inside towards the outside of the electromagnetic wave absorbing material.

3. The electromagnetic wave absorbing material of claim 1, wherein the iron oxide is represented as follows,
MₓFe₂₋ₓO₃
wherein M is an element having an oxidation number of +1, +2, +3, +4, +5, or +6; and x is a value between greater than or equal to 0 and less than 1.

4. The electromagnetic wave absorbing material of claim 3, wherein the M is at least one metal element selected from a group consisting of molybdenum, zirconium, magnesium, cerium, lanthanum, yttrium, titanium, silver, aluminum, gallium, barium, rhodium and nickel.

5. The electromagnetic wave absorbing material of claim 1, wherein the inorganic compound is at least one selected from a group consisting of silicon oxide, zirconium oxide, vanadium oxide, boron nitride, and aluminum nitride.

6. The electromagnetic wave absorbing material of claim 1, wherein the inorganic compound selected from a group consisting of silicon oxide, and a molar ratio of silicon/iron within the electromagnetic wave absorbing material is 0.04 to 12.

7. The electromagnetic wave absorbing material of claim 1, wherein the inorganic compound comprises zirconium oxide, and a molar ratio of zirconium/iron within the electromagnetic wave absorbing material is 0.01 to 3.

8. The electromagnetic wave absorbing material of claim 1, wherein the shell layer has a thickness of 1 to 50 nm.

9. The electromagnetic wave absorbing material of claim 1, wherein the core accounts for 5 to 95 volume percent of the entire electromagnetic wave absorbing material, and the shell layer accounts for 5 to 95 volume percent of the entire electromagnetic wave absorbing material.

10. A method for manufacturing an electromagnetic wave absorbing material, comprising:
providing a shell layer material precursor and a core material precursor;
coating the core material precursor with the shell layer material precursor to form a combination;
sintering the combination at a high temperature to form a core and a shell layer, and materials of the core and the shell layer diffuse with each other; and
etching the shell layer.

11. A composite structure for suppressing electromagnetic interference, comprising the electromagnetic wave absorbing material according to claim 1, a functional filler, and a matrix.

12. The composite structure of claim 11, wherein the electromagnetic wave absorbing material accounts for 5 to 95 volume percent of the entire composite structure.

13. The composite structure of claim 11, wherein the functional filler accounts for greater than or equal to 5 volume percent of the entire composite structure, and the functional filler contains at least one compound selected from a group consisting of silicon dioxide, boron nitride, aluminum nitride, and silicon carbide.

14. The composite structure of claim 11, wherein the matrix accounts for greater than or equal to 5 volume percent of the entire composite structure, and the matrix contains epoxy resin, polypropylene resin, or polyimide resin.
